(19) United States
(12) Patent Application Publication
(10) Pub. No.: US 2009/0032097 A1
(43) Pub. Date: Feb. 5, 2009

(54) Enhancement of dye-sensitized solar cells using colloidal metal nanoparticles

(76) Inventors: Terry P. Bigioni, Toledo, OH (US); Robert W. Collins, Maumee, OH (US)

Correspondence Address: EMCH, SCHAFFER, SCHAUB & PORCELLO CO, P O BOX 916, ONE SEAGATE SUITE 1980, TOLEDO, OH, 43697, US

(21) Appl. No.: 12/220,862

(22) Filed: Jul. 29, 2008

Related U.S. Application Data
(60) Provisional application No. 60/962,682, filed on Jul. 31, 2007.

(51) Int. Cl. H01L 31/00; H01L 21/02

(52) U.S. Cl. 136/256; 438/57; 257/E21.002; 977/774

(57) ABSTRACT

Plasmon enhancement of a dye-stained matrix for use in a photovoltaic cell. The matrix includes nanoparticles of a charge accepting semiconductor; a sensitizer coating the charge accepting semiconductor; and metal nanoparticles capable of plasmon resonance. Another aspect of the invention relates to a plasmon-enhanced photovoltaic cell. The solar photovoltaic cell includes a plurality of nanoparticles of charge accepting semiconductor; a coating of sensitizer on the plurality of nanoparticles of charge accepting semiconductor; and a plurality of metal nanoparticles capable of plasmon resonance in communication with the sensitizer coating. An additional aspect relates to a method of making plasmon-enhanced material suitable for use in a photovoltaic cell. The steps include providing a charge accepting semiconductor; sintering the charge accepting semiconductor such as metal oxide; coating the charge accepting semiconductor with sensitizer; providing metal nanoparticles capable of plasmon resonance; and coating the charge accepting semiconductor with metal nanoparticles capable of plasmon resonance.

### CROSS REFERENCE TO RELATED APPLICATIONS

This application claims the benefit of provisional patent application Ser. No. 60/962,682 filed on Jul. 31, 2007.

### BACKGROUND OF THE INVENTION

Existing dye-sensitized solar cells utilize dye as the active component. The dye absorbs light and converts it into electronic energy. The rest of the cell acts to extract that energy and to complete the circuit. Typically, current dyes being used in solar cells do not collect all of the incident light efficiently. To absorb all of the incident light, the photoactive layer of the solar cell must be made very thick, which in turn impedes charge transport and energy extraction from the cell. Metals particles typically absorb light 100-1000× more efficiently than most dyes. Metal particles absorb light more efficiently due to a plasmon resonance, which is responsible for surface enhanced Raman scattering and metal enhanced fluorescence.

When light is absorbed by a metal nanoparticle it excites a collective oscillation of electrons at the frequency of the incident light. When this excitation is at a resonant frequency, the charge oscillation results in a plasmon polariton. Energy is localized in this plasmon mode in the form of an intense field in the immediate vicinity of the nanoparticle. This field efficiently couples to electronic excitations of molecules as is well known in the surface-enhanced Raman scattering effect and plasmon-enhanced luminescence and provides a more efficient pathway to electronically excite dye molecules from the incident light.

### SUMMARY OF THE INVENTION

This invention uses metal particles to absorb the light with higher efficiency and to couple this energy with dye molecules. A typical procedure for preparing the cell is as follows: first a TiO₂ matrix is fabricated and then stained with a dye following accepted procedures. Next, nanoparticles are applied, for example by soaking the dye stained matrix in a liquid solution of colloidal nanoparticles. Finally, the solar cell is assembled and an electrolyte is added. Since these nanoparticles are in a colloidal form, this allows them to impregnate the TiO₂ matrix and saturate the matrix along side the dye molecules. This ensures that the maximum number of dye molecules in the solar cell have an opportunity to absorb energy from the metal nanoparticles, thereby further enhancing the photon-to-current conversion efficiency. The increased absorptivity of the stained matrix also allows the solar cell to absorb more energy closer to the electrode. This decreases the distance that electrons in the charge accepting semiconductor need to travel. It also decreases the distance that ions in the electrolyte need to travel. Decreasing these charge transport distances can reduce losses due to trapping, recombination and limited charge mobility inside the cell.

The colloidal particles can be applied in such a way as to control the number density of nanoparticles in the solar cell in order to optimize its performance. Further, metal nanoparticles with different spectral responses can be applied in order to capture more of the useful part of the solar spectrum. In addition, dyes may be chemically bound to the nanoparticles, matching the spectral response of the nanoparticles with that of the dye, where nanoparticle-dye pairs are selected in such a way as to capture more of the useful part of the solar spectrum.

Other objects and advantages of the present invention will become apparent to those skilled in the art upon a review of the following detailed description of the preferred embodiments and the accompanying drawings.

### BRIEF DESCRIPTION OF THE DRAWINGS

FIG. 1 shows a prior art solar cell film.

FIG. 2 shows an additional prior art solar film.

FIG. 3 shows the dye sensitized solar cell of the current invention.

FIG. 4 is a graph showing the absorption spectrum of gold nanoparticles and anthocyanim dyes.

FIG. 5 is a schematic diagram of nanocrystalline photovoltaic cell.

FIG. 6 is a side view of the photovoltaic cell of FIG. 5.

### DETAILED DESCRIPTION OF THE PREFERRED EMBODIMENT(S)

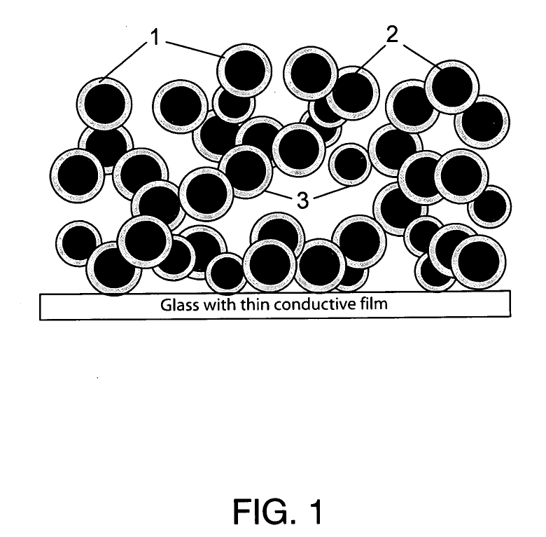

In the prior art solar cell film shown in FIG. 1 the particles in this figure comprises a metal nanoparticle (2) surrounded by a TiO₂ layer (1) with a dye outside layer (3). This method has the advantage of a high loading of metal nanoparticles that are always in the proximity of the dye. It is unclear, however, whether the dye molecules are close enough to the metal nanoparticles to benefit markedly from field enhancement. It is also unclear how integrating the metal nanoparticles in this way might affect electron transport, trapping, and recombination. The disadvantages of this method are that the density of metal nanoparticles cannot be varied (i.e. one metal particle per semiconductor particles), and can only be optimized for one part of the solar spectrum since there is no direct link between nanoparticle and dye molecule. The prior method describes a technique that uses metal nanoparticles that are encapsulated in TiO₂ to form core-shell particles. These particles are then sintered to form the matrix, with the metal nanoparticles embedded within the matrix and dye coating the outside of the TiO₂ shells. This prior method requires a more sophisticated synthetic method to produce the core-shell nanoparticles. This prior method also has a large space between the metal core and the dye molecules, which reduces the coupling efficiency.

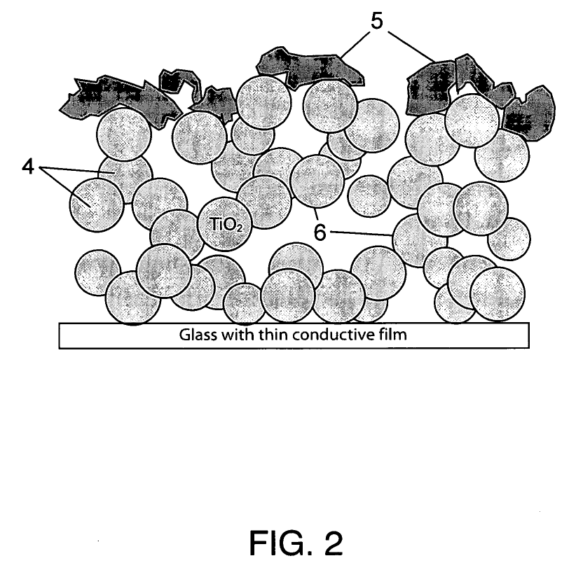

In FIG. 2, TiO₂ particles (4) are surrounded by a dye layer (6). In this film, silver atoms (5) are thermally evaporated onto the surface of the dye-sensitized solar cell. The silver atoms form nanoscale grains on the outer surface of the sensitized matrix. These grains can support surface plasmons so the dye molecules near the outer surface of the matrix, and therefore near the grains, can couple to the strong oscillating fields. In this embodiment, dye molecules that are deep within the matrix are not involved in the plasmon-induced enhancement process. The coupling to the dye is therefore limited to a small volume of the matrix. The photocurrent enhancement is thereby less effective than the herein described method, which impregnates the entire dye-saturated matrix with metal particles. Also, the prior method required a vacuum thermal evaporation step, whereas the method described herein only requires the application of a liquid solution to the solar cell.

The active component in a dye-sensitized solar cell (DSSC) is the dye, which absorbs light and converts it into electronic energy. The rest of the cell acts to extract that energy and to complete the circuit. The current dyes being used in DSSCs are not efficiently collecting all of the incident light for typical cell thicknesses. Metal nanoparticles typically absorb light 100-1000× more efficiently than most dyes. This is due to the surface plasmon resonance which is responsible for surface-enhanced Raman scattering and metal-enhanced fluorescence.

When light is absorbed by a metal nanoparticle it excites a collective oscillation of electrons at the frequency of the incident light. When this excitation is at a resonant frequency, the charge oscillation results in a plasmon polariton. Energy is localized in this plasmon mode in the form of an intense field in the immediate vicinity of the nanoparticle. This field efficiently couples to electronic excitations of molecules, as is well known in the surface-enhanced Raman scattering effect and plasmon-enhanced luminescence, and provides a more efficient pathway to electronically excite dye molecules from the incident light.

This invention uses metal nanoparticles to absorb the light with higher efficiency and to couple this energy to the dye molecules in the DSSC. A typical procedure for preparing a cell is as follows: first a TiO₂ matrix is fabricated and then stained with a dye, following accepted procedures. Next, nanoparticles are applied, for example by soaking the dye-stained matrix in a liquid solution of colloidal nanoparticles. Finally, the solar cell is assembled and an electrolyte is added, following accepted procedures. Since these nanoparticles are in a colloidal form, this allows them to impregnate the TiO₂ matrix and saturate the matrix along side the dye molecules. This ensures that all of the molecules in the DSSC have an opportunity to absorb energy from the metal nanoparticles, thereby further enhancing the photon-to-current conversion efficiency. The increased absorptivity of the stained matrix allows the solar cell to absorb more energy closer to the electrode. This decreases the distance that electrons in the charge accepting semiconductor need to travel. It also decreases the distance that ions in the electrolyte need to travel. Decreasing these charge transport distances can reduce losses due to trapping, recombination and limited charge mobility inside the cell.

The colloidal particles can be applied in such a way as to control the number density of nanoparticles in the solar cell, in order to optimize performance. An insulating coating may also be applied to the metal nanoparticles to reduce the effects of charge trapping by the metal, which can promote recombination. This coating can also impart solubility properties to the nanoparticle and ensure non-solubility in the electrolyte. Metal nanoparticles with different spectral responses can be applied, in order to capture more of the useful part of the solar spectrum. Dyes can be chemically bound to the metal nanoparticles, matching the spectral response of the nanoparticles with that of the dye, where nanoparticle-dye pairs are selected in such a way as to capture more of the useful part of the solar spectrum.

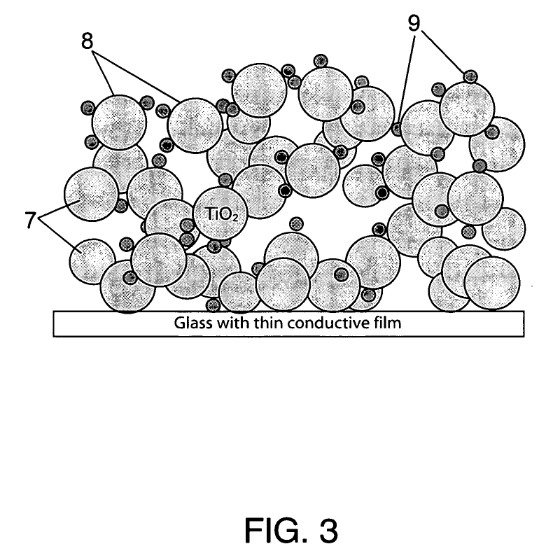

As shown in FIG. 3, the nanoporous TiO₂ matrix is first fabricated using standard methods. The TiO₂ particles (7) are surrounded by a dye layer (8). The dye sensitized matrix is further sensitized by the application of colloidal metal nanoparticles (9). The metal nanoparticles (9) are selected to have a resonance matching the absorption band of the dye (8). Additional metal nanoparticles (9) may be applied to optimize the performance of the cell.

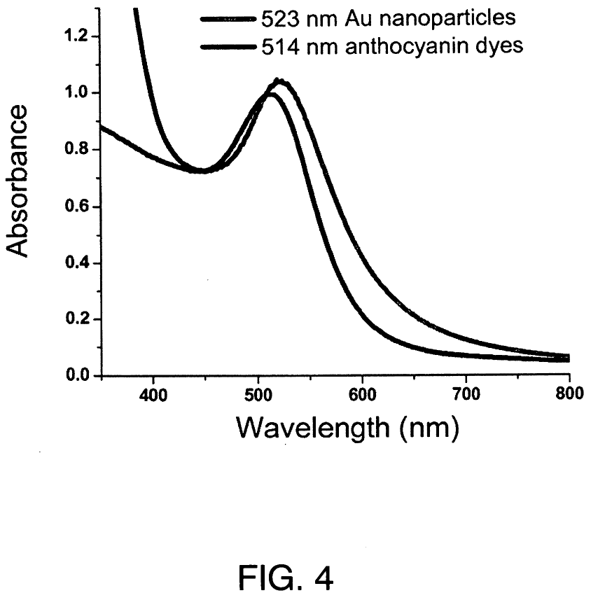

FIG. 4 shows the absorption spectra of gold nanoparticles and anthocyanin dyes, which could be used in a dye-sensitized solar cell. The peak at 523 nm in the nanoparticle spectrum is due to the surface plasmon resonance, which efficiently captures photons and converts the solar energy into an intense local field, oscillating at the plasmon frequency (corresponds to the peak center). The peak at 514 nm in the dye spectrum corresponds to the electronic excitation that leads to carrier generation in the solar cell. When the absorption band of the dye is carefully matched to the plasmon band of the nanoparticle, the intense local field can efficiently couple to the electronic excitation in the dye molecule. This provides a more efficient way to convert photons into electronic excitations than through direct absorption by the dye molecule alone.

The plasmon resonant materials are metal particles such as gold, silver or copper particles. Metal particles of different materials, sizes, and geometries can be utilized to collect light from as much of the solar spectrum as possible. An insulating coating can be applied to the metal nanoparticles to prevent charge trapping on the metal, to impart solubility properties to the nanoparticle, and to ensure non-solubility in the electrolyte. The sensitizer coating can be a dye, an organic dye, a small band-gap semiconductor or a quantum dot. The sensitizer coating can be linked to the nanoparticles and a number of colors can be combined to collect light from a broader solar spectrum. The charge accepting semiconductor can be a metal oxide such as TiO₂ or ZnO. The charge accepting semiconductor can be in the form of nanoparticles, nanowires, composites of such structures, or other structural forms.

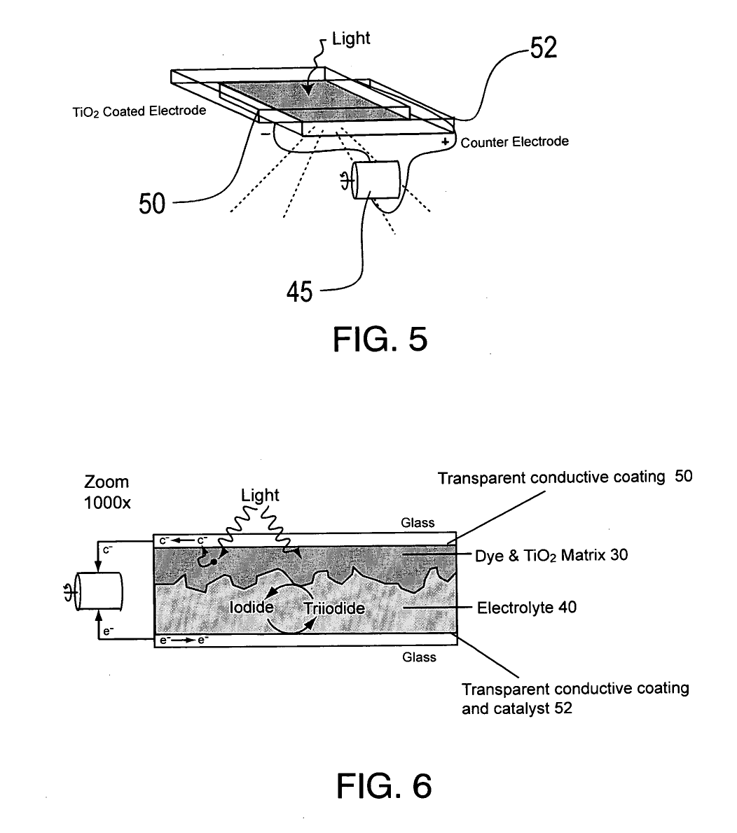

As shown in FIGS. 5 and 6 the photovoltaic cell has a matrix (30) of a plurality of nanoparticles of a charge accepting semiconductor, a sensitizer coating the charge accepting semiconductor, and a plurality of metal nanoparticles capable of plasmon resonance. The dye-stained and metal nanoparticle-loaded matrix is placed in contact with a hole conductor, such as an electrolyte (40) between two transparent electrodes (50, 52). A load (45) is then connected to the electrodes. When light is absorbed by the dye, an electron is released into the charge accepting semiconductor and makes its way to one of the electrodes (50). The presence of the plasmon resonant nanoparticles enhances the absorption of light by the sensitizer. To reduce the sensitizer (for example a dye), electrons are returned by way of the second electrode (52) to pass into the hole conductor (such as an electrolyte), which then returns the electrons to the sensitizer.

The above detailed description of the present invention is given for explanatory purposes. It will be apparent to those skilled in the art that numerous changes and modifications can be made without departing from the scope of the invention. Accordingly, the whole of the foregoing description is to be construed in an illustrative and not a limitative sense, the scope of the invention being defined solely by the appended claims.

We claim:

1. A plasmon enhanced dye sensitized matrix comprising:
a. a charge accepting semiconductor material;
b. a sensitizer coating the charge accepting semiconductor material; and
c. nanoparticles capable of plasmon resonance operatively associated with the semiconductor material and the sensitizer coating.

2. The matrix of claim 1 wherein the nanoparticles are metal particles capable of supporting plasmon resonance.

3. The matrix of claim 2 wherein the nanoparticles are gold.

4. The matrix of claim 2 wherein the nanoparticles are silver.

5. Nanoparticles of claim 3 or 4 wherein the nanoparticles have an insulating coating.

6. Nanoparticles of claim 5 wherein the insulating coating is made up of a plurality of alkane thiol molecules.

7. The matrix of claim 1 wherein the charge accepting semiconductor is TiO₂.

8. The matrix of claim 1 wherein the charge accepting semiconductor is ZnO.

9. The matrix of claim 1 wherein the sensitizer coating is an organic dye.

10. The matrix of claim 1 wherein the sensitizer coating is a small band-gap semiconductor.

11. The matrix of claim 1 wherein the sensitizer is a quantum dot.

12. A plasmon enhanced solar photovoltaic cell comprising:
a. a matrix formed of a plurality of nanoparticles of charge accepting semiconductor;
b. a coating of sensitizer on the matrix; and
c. a coating of a plurality of nanoparticles capable of plasmon resonance on the matrix.

13. The plasmon enhanced photovoltaic cell of claim 12 further comprising a hole conductor in communication with the coating of sensitizer.

14. The plasmon enhanced photovoltaic cell of claim 13 further comprising an electrode in communication with the hole conductor.

15. A method of making a plasmon enhanced material suitable for use in a photovoltaic cell comprising the steps of:
providing a charge accepting semiconductor;
sintering the charge accepting semiconductor to form a material;
coating the charge accepting semiconductor with a sensitizer; and
coating the charge accepting semiconductor with nanoparticles capable of plasmon resonance.

16. The method of claim 15 in which the nanoparticle is a metal particle capable of supporting plasmon resonance.

17. The method of claim 16 wherein the nanoparticle is gold.

18. The method of claim 16 wherein the nanoparticle is silver.

19. The method of claim 15 wherein the charge accepting semiconductor is TiO₂.

20. The method of claim 15 wherein the charge accepting semiconductor is ZnO.

21. The method of claim 15 wherein the sensitizer is an organic dye.

22. The method of claim 15 wherein the sensitizer is a small band-gap semiconductor.

23. The method of claim 15 wherein the sensitizer is a quantum dot.
